(19) United States
(12) Patent Application Publication
(10) Pub. No.: US 2022/0119676 A1
(43) Pub. Date: Apr. 21, 2022

(54) POLYAMIC ACID COMPOSITION FOR MANUFACTURING DISPLAY SUBSTRATE AND METHOD FOR MANUFACTURING SUBSTRATE FOR DISPLAY BY USING SAME

(71) Applicant: PI ADVANCED MATERIALS CO., LTD., Chungcheongbuk-do (KR)

(72) Inventors: Gyeong Hyeon Ro, Gyeongsangnam-do (KR); Ik Sang Lee, Gyeongsangbuk-do (KR)

(21) Appl. No.: 17/417,643

(22) PCT Filed: Nov. 29, 2019
(86) PCT No.: PCT/KR2019/016798

§ 371 Date: Jun. 23, 2021

(30) Foreign Application Priority Data
Dec. 24, 2018 (KR) 10-2018-0168515
May 24, 2019 (KR) 10-2019-0061188

(51) Int. Cl. C09D 179/08; C08G 73/10; H01L 27/12; B29C 41/00; B29C 41/42

(52) U.S. Cl. CPC C09D 179/08; C08G 73/1067; H01L 27/1218; B29K 2079/08; B29C 41/003; B29C 41/42; H01L 27/1266

(57) ABSTRACT

The present invention provides a polyamic acid composition, which, in a cured state on a substrate of amorphous or crystalline silicon, has an adhesion of 0.05-0.1 N/cm with the amorphous or crystalline silicon.

### TECHNICAL FIELD

### Cross-Reference to Related Applications

This application claims the benefit of priority based on Korean Patent Application No. 10-2018-0168515 filed on Dec. 24, 2018 and Korean Patent Application No. 10-2019-0061188 filed on May 24, 2019, the disclosures of which are incorporated herein by reference in their entirety.

### Technical Field

The present invention relates to a polyamic acid composition for manufacturing a display substrate and a method for manufacturing a display substrate using the same.

### BACKGROUND

Display devices have been rapidly developed mainly on flat panel displays (FPDs), which are easy to have a large area and are capable of thinning and lightweight. Such a flat panel display includes a liquid crystal display (LCD), an organic light emitting display (OLED) or an electrophoretic element, and the like.

Recently, in order to further expand the application and use of such a flat panel display, a flexible display to which a flexible substrate is applied has been developed. Such a display is mainly applied to mobile devices such as smart phones and tablet PCs, and the application fields thereof are expanded.

The display substrate constituting the flexible display may be manufactured by a process of forming a thin film transistor device structure on a flexible substrate (TFTs on Plastic (TOP)). However, the process is performed at a high temperature of 300° C. or higher, or 400° C. or higher, where a polyimide-based material having flexible properties together with the highest level of heat resistance and mechanical properties among organic polymer materials is preferably utilized as the flexible substrate.

Typically, the display substrate may be manufactured by (i) coating a polyamic acid solution, which is a precursor of polyimide, on a sacrificial layer made of amorphous or crystalline silicon and curing it to form a polyimide resin, which is a flexible substrate, and then (ii) performing a process of forming the thin film transistor device structure on the flexible substrate made of the polyimide resin and (iii) peeling the sacrificial layer, if such a process is completed, from the flexible substrate using a laser having a predetermined wavelength.

In the manufacture of the display substrate where a desired quality is inherent, various process variables can act in combination, but one particularly important thing is that the polyimide resin, which is the flexible substrate, is bonded to the sacrificial layer at an appropriate level.

The above-mentioned appropriate level means a level that in a process of forming a thin film transistor device structure on a polyimide resin, the bonding state and shape of the sacrificial layer with the polyimide resin are maintained firmly, but when the sacrificial layer is removed after this process, the sacrificial layer can be easily peeled off from the polyimide resin.

If the adhesion of the polyimide resin to the sacrificial layer is poor, serious damage that the polyimide resin or the sacrificial layer is eliminated may occur in the process of forming thin film transistors on the polyimide resin.

Conversely, if the adhesion is excessive beyond a certain level, a portion of the sacrificial layer may remain in a state bonded to the polyimide resin or the ash derived from the sacrificial layer may be bonded to the polyimide resin, in the process of peeling the sacrificial laver with a laser. Accordingly, the polyimide resin may be damaged during the peeling process, and the quality of the display substrate obtained by peeling may be deteriorated. In addition, if the energy of the laser is amplified to completely peel the sacrificial layer maintaining the strong bonding state, the polyimide resin or the thin film transistor device structure may be damaged or destroyed.

Therefore, there is a need for a novel polyimide-based material capable of solving the above-described technical problem.

### DISCLOSURE

### Technical Problem

It is an object of the present invention to provide a novel polyamic acid composition capable of solving the conventional problems recognized above at once.

According to one aspect of the present invention, the polyamic acid composition may have, in a cured state on a substrate of amorphous or crystalline silicon, that is, when converted into a polyimide resin, adhesion of 0.05 to 0.1 N/cm with the amorphous or crystalline silicon.

Such adhesion is particularly preferable in that in the process of forming the thin film transistor device structure on the polyimide resin derived from the polyamic acid composition, the boding state and shape of the amorphous or crystalline silicon, which is the sacrificial layer, with the polyimide resin are maintained firmly, but when the sacrificial layer is removed after this process, the sacrificial layer can be easily peeled off from the polyimide resin.

The above-described problem can be solved by such an aspect, and the present invention provides specific embodiments for its implementation.

### Technical Solution

In one embodiment, the present invention provides a polyamic acid composition

comprising a polyamic acid polymer in which an aromatic dianhydride-based monomer and an aromatic diamine-based monomer are polymerized,

wherein the aromatic dianhydride-based monomer comprises a first component having a biphenyl structure, a second component having one benzene ring and a third component having a benzophenone structure, and

the polyamic acid composition has, in a cured state on a substrate of amorphous or crystalline silicon, adhesion of 0.05 to 0.1 N/cm with the amorphous or crystalline silicon, and

has, in a cured state on a substrate of amorphous or crystalline silicon, adhesion of 0.01 N/cm or less as measured after irradiation with a laser having a wavelength of 308 nm at 150 mJ/cm². The adhesion may be adhesion as measured while attaching the cured polyamic acid composition to the amorphous or crystalline silicon substrate so that its width becomes 1 cm, and peeling it at a peel rate of 20 mm/min and a peel angle of 180°, according to ASTM D 3359.

In one embodiment, the present invention is a method for manufacturing a display substrate using a polyamic acid composition, and

Hereinafter, embodiments of the present invention will be described in more detail in the order of “a polyamic acid composition and “a method of manufacturing a display substrate” according to the present invention.

Prior to this, the terms or words used in this specification and claims should not be construed as being limited to their usual or dictionary meanings, but should be interpreted as meanings and concepts consistent with the technical idea of the present invention based on the principle that the inventors can appropriately define the concept of terms in order to explain their own invention in the best way.

Therefore, the constitutions of the examples described in this specification are each only one of the most preferable examples of the present invention and do not represent all the technical idea of the present invention, so that it should be understood that various equivalents and modifications capable of replacing them at the time of the present application may exist.

In this specification, the singular expressions include plural expressions, unless the context clearly indicates otherwise. In this specification, the term such as “comprise,” “include” or “have” is intended to designate the presence of implemented features, numbers, steps, components or combinations thereof, but it should be understood that the presence or addition possibility of one or more other features or numbers, steps, components, or combinations thereof is not excluded in advance.

In this specification, the “dianhydride” is intended to include its precursors or derivatives, which may not be technically the dianhydride, but nevertheless, they will react with diamines to form polyamic acids, and these polyamic acids can be converted back to polyimides.

In this specification, the “diamine” is intended to include its precursors or derivatives, which may not be technically the diamine, but nevertheless, they will react with dianhydrides to form polyamic acids, and these polyamic acids can be converted back to polyimides.

When amounts, concentrations, or other values or parameters herein are given as enumeration of ranges, preferred ranges, or preferred upper limits and preferred lower limits, it should be understood to specifically disclose all ranges capable of being formed of any pair of any upper range limit or preferred value, and any lower range limit or preferred value, regardless of whether ranges are disclosed separately. When a range of numerical values is referred to herein, the range is intended to include the end-point value and all integers and fractions within the range, unless otherwise stated, for example, unless there is a limiting term such as more than or less than. It is intended that the scope of the invention is not limited to the specific values mentioned when defining the range.

Polyamic Acid Composition

The polyamic acid composition according to the present invention comprises

a polyamic acid polymer in which an aromatic dianhydride-based monomer and an aromatic diamine-based monomer are polymerized,

wherein the aromatic dianhydride-based monomer comprises a first component having a biphenyl structure, a second component having one benzene ring and a third component having a benzophenone structure, and

the polyamic acid composition may have, in a cured state on a substrate of amorphous or crystalline silicon, adhesion of 0.05 to 0.1 N/cm with the amorphous or crystalline silicon, and

have, in a cured state on a substrate of amorphous or crystalline silicon, adhesion of 0.01 N/cm or less as measured after irradiation with a laser having a wavelength of 308 nm at 150 mJ/cm².

Specifically, the polyamic acid composition of the present invention may comprise an organic solvent; and

a polyamic acid formed by polymerizing an aromatic dianhydride-based monomer and an aromatic diamine-based monomer.

The aromatic dianhydride-based monomer may comprise a first component having a biphenyl structure, a second component having one benzene ring, and a third component having a benzophenone structure.

The aromatic diamine-based monomer may comprise a diamine component having one benzene ring in an amount of more than 50 mol % relative to the total number of moles thereof, and specifically, may comprise it in an amount of 60 mol % or more, or 70 mol % to 100 mol % relative to the total number of moles thereof.

The content of the first component may be 50 to 70 mol % relative to the total number of moles of the aromatic dianhydride-based monomer. Specifically, the content of the first component may be 50 mol % to 65 mol %, 55 mol % to 70 mol %, 55 mol % to 65 mol %, 57 mol % to 62 mol % or 58 mol % to 60 mol %, relative to the total number of moles of the dianhydride-based monomer.

The content of the second component may be 20 mol % to 40 mol % relative to the total number of moles of the aromatic dianhydride-based monomer. Specifically, the content of the second component may be 20 mol % to 35 mol %, 25 mol % to 40 mol %, 25 mol % to 35 mol %, 30 mol % to 40 mol %, 32 mol % to 38 mol % or 35 to 38 mol %, relative to the total number of moles of the dianhydride monomer.

The content of the third component may be more than 1 mol % to less than 7 mol % relative to the total number of moles of the aromatic dianhydride-based monomer. Specifically, the content of the third component may be 2 mol % to 5 mol % or 3 mol % to 5 mol %.

The polyamic acid composition may have, in a cured state on a substrate of amorphous or crystalline silicon, adhesion of 0.05 to 0.1 N/cm with the amorphous or crystalline silicon. Specifically, it may have adhesion of 0.05 to 0.09 N/cm, 0.06 to 0.1 N/cm, or 0.06 to 0.09 N/cm, with the amorphous or crystalline silicon.

The polyamic acid composition may also be cured by heat treatment to form a polyimide resin. The polyamic acid composition may be heat-treated at 20° C. to 550° C. or 20° C. to 500° C. to prepare a polyimide resin, and the polyimide resin prepared by such a polyamic acid composition may indwell excellent physical properties as follows.
Coefficient of thermal expansion of 8 ppm/° C. or less
Glass transition temperature of 490° C. or higher
Decomposition temperature of 555° C. or higher
Tensile strength of 350 MPa or more
Elongation of 20% or more
Transmittance of 60% or more

In one example, the coefficient of thermal expansion of the polyimide resin according to the present invention may be 7.7 ppm/° C. or less, 7.5 ppm/° C. or less, 6 to 8 ppm/° C., or 6 ppm/° C. to 7 ppm/° C.

In addition, the glass transition temperature of the polyimide resin according to the present invention may be 495° C. or higher, 500° C. or higher, 490° C. to 520° C., 490° C. to 510° C. or 500° C. to 550° C., the decomposition temperature of the polyimide resin according to the present invention may be 560° C. or higher, 555° C. to 600° C., or 555° C. to 580° C.

Furthermore, the tensile strength of the polyimide resin according to the present invention may be 350 MPa or more, 360 MPa or more, 370 MPa or more, 350 to 400 MPa or 360 to 390 MPa; the elongation of the polyimide resin according to the present invention may be 22% or more, 20% to 30%, 20% to 28%, or 22% to 26%; and the transmittance of the polyimide resin according to the present invention may be 60% to 70%, 60% to 65%, or 60% to 62%.

In this regard, the polyamic acid composition of the present invention that can satisfy all of the above physical properties and the polyimide resin manufactured thereby can be preferably utilized as a material for a display substrate.

Polyimide resins capable of expressing all of these physical properties and polyamic acid compositions implementing the same are novel polyimide-based materials that have not been known so far, and the configuration thereof will be described in more detail below through non-limiting examples.

<Adhesion>

In general, the amorphous or crystalline silicon substrate may be non-restrictively used for manufacturing a display substrate, and in particular, may be used as a sacrificial layer that has been bonded to and removed from a flexible substrate when manufacturing a display substrate. At this time, the polyamic acid composition of the present invention may be cured on the amorphous or crystalline silicon substrate to form a polyimide resin, and the polyimide resin may be preferably used as a flexible substrate.

An amorphous or crystalline silicon substrate as the sacrificial layer is present in a state bonded to a polyimide resin in the process of forming a thin film transistor (TFT) device structure, and after this process, if the amorphous or crystalline silicon substrate is irradiated with a laser, the amorphous or crystalline silicon substrate and the polyimide resin release the boding state, thereby allowing to be peeled off from each other.

However, it should be noted that if the adhesion is slightly out of the range described in the present invention, the polyimide resin or the thin film transistor devices formed on the polyimide resin may be greatly damaged.

For example, when the adhesion is slightly exceeded, this can lead to an unfavorable aspect in which at least a part of the amorphous or crystalline silicon substrate is maintained in a state of being bonded to the polyimide resin despite the treatment of the amorphous or crystalline silicon substrate using a laser. In such an aspect, a portion of the polyimide resin maintained in the bonding state may be broken by the amorphous or crystalline silicon substrate.

In addition, the ash derived from the amorphous or crystalline silicon substrate may be bonded to the polyimide resin.

In another aspect, it is possible to consider inducing the peeling of the amorphous or crystalline silicon substrate by using a higher energy laser, but in this case, as the higher energy laser affects the polyimide resin and the thin film transistor device structure, having a thickness in nanometers to micrometers, their damage, for example decomposition, deformation, or fracture of the resin and/or the transistor devices can be caused. In addition, the higher energy laser can generate relatively more ash derived from the amorphous or crystalline silicon substrate, and the ash can act as a foreign material to impair, for example, the quality of the transistor devices.

When the adhesion is satisfied, the bonding between the polyimide resin and the amorphous or crystalline silicon substrate may be well maintained at a high temperature of about 300° C. or higher, or about 400° C. or higher.

This is the main reason that makes it difficult for the polyimide resin to be used as a flexible substrate, which is because the process of forming a thin film transistor device structure on the polyimide resin is performed at a high temperature of about 300° C. or higher. Under relatively low adhesion compared to the scope of the present invention, at least a part of the polyimide resin may be peeled off to cause an excited state, or the peeled part may be rolled to form a curl, and in this case, the process cannot proceed.

In summary, it is important that the adhesion between the polyimide resin and the amorphous or crystalline silicon substrate is extremely limited and falls within the most preferred range, and the present invention provides such a preferred range as described above. In addition, the polyamic acid composition of the present invention may exhibit adhesion within the above range to an amorphous or crystalline silicon substrate in a cured state.

Furthermore, the polyamic acid composition of the present invention may have, in a cured state on a substrate of amorphous or crystalline silicon, adhesion of 0.01 N/cm or less after irradiation with a laser having a wavelength of 308 nm at 150 mJ/cm². The adhesion after the laser irradiation is at a very insignificant level, which may be a level where the bonding state with the amorphous or crystalline silicon substrate cannot be substantially maintained, and accordingly, for example, after the process of forming a thin film transistor device structure, the polyimide resin derived from the polyamic acid composition can be easily peeled off from the amorphous or crystalline silicon substrate, and its shape can also be maintained intact.

The present invention provides a method of curing a polyamic acid composition to form a polyimide resin, and testing adhesion in this state.

In the test method,

the required force is measured, in a state where a polyamic acid composition is applied on an amorphous or crystalline silicon substrate with a width of 1 cm*a length of 10 cm and heat-treated to form a polyimide resin thin film of about 10 μm to 20 μm or 13 μm to 17 μm, while attaching a tape with a width of 1 cm to the end of the polyimide resin and peeling the polyimide resin from the substrate using this tape.

The method of measuring adhesion after laser treatment may be used by the following method:

The required force is measured, in a state where a polyamic acid composition is applied on an amorphous or crystalline silicon substrate with a width of 1 cm*a length of 10 cm and heat-treated to form a polyimide resin thin film of about 10 μm to 20 μm or 13 μm to 17 μm, while irradiating the crystalline silicon substrate with a laser having a wavelength of 308 nm, and then attaching a tape with a width of 1 cm to the end of the polyimide resin and peeling the polyimide resin from the substrate using this tape.

The use of the third component having a benzophenone structure may be the main reason for the fact that the adhesion of the cured polyamic acid composition can satisfy the limiting and most preferable range described in the present invention.

Specifically, in the polyamic acid composition of the present invention, the polymer chain of the polyamic acid may comprise a benzophenone structure by a third component having a benzophenone structure, and this benzophenone structure may also be maintained in the polyimide polymer chain converted by the polyamic acid polymer chain. The benzophenone structure can improve adhesion through interaction with a polar functional group such as a hydroxy group present on the surface of an amorphous or crystalline silicon substrate, and when the structure of the third component, and its content satisfy the scope of the present invention, they may at last act mainly in expressing adhesion to an object to be bonded, such as an amorphous or crystalline silicon substrate, in a desired level.

Conventional polyimide resins belong to the side with extremely low adhesion, and, for example, may have low adhesion of less than 0.05 N/cm with regard to an amorphous or crystalline silicon substrate. It can be regarded as one cause that the polyimide resin comprises a weak boundary layer (WBL) at the contact interface with the amorphous or crystalline silicon substrate. There are various forms of the weak boundary layer, but one of them is that at least a part of the polyimide resin at the contact interface may be in a lifted form, without supporting an amorphous or crystalline silicon substrate.

The lifted form may be caused, for example, by weak attractive force acting at the interface between the polyimide resin and the amorphous or crystalline silicon substrate, or by moisture and/or an organic solvent, and the like that volatilize when a polyamic acid composition is converted to a polyimide resin.

The third component may improve the bonding level of the polyimide resin through the interaction of the benzophenone structure with the polar functional groups present in the amorphous or crystalline silicon substrate.

In addition, the benzophenone structure of the third component may be advantageous in that the volatilization of moisture and/or organic solvent is easily achieved at the initial point of conversion from the polyamic acid composition to the polyimide resin, and accordingly, the third component may advantageously act in suppressing a phenomenon that the conversion-completed polyimide resin is lifted from the amorphous or crystalline silicon substrate.

Consequently, the third component acts advantageously in minimizing the formation of such a weak boundary layer in the polyimide resin, whereby it may be related to the polyimide resin having the desired level of adhesion.

However, it is not preferable to use an excessive amount of the third component in consideration of only the above-described advantages, and the reason is because the adhesion of the polyimide resin to the amorphous or crystalline silicon substrate is remarkably increased and can easily exceed 0.1 N/cm.

In addition, the use of the third component may lower the glass transition temperature of the polyimide resin and excessively increase the coefficient of thermal expansion, which is not preferable for the manufacture of a display substrate manufactured by, for example, chemical/physical interaction with an inorganic substance.

Therefore, the content of the third component should be particularly carefully selected in the range that the adhesion of the polyimide resin may fall within the range of 0.05 to 0.1 N/cm and the glass transition temperature and the coefficient of thermal expansion are not implemented in a non-preferred aspect.

In one example of this, the content of the third component may be more than 1 mol % to less than 7 mol %, relative to the total number of moles of the aromatic dianhydride-based monomer, and specifically, the content of the third component may be 2 mol % to 5 mol % or 3 mol % to 5 mol %.

In the present invention, the third component having a benzophenone structure may be 3,3′,4,4′-benzophenone tetracarboxylic dianhydride (BTDA).

<Other Physical Properties>

The third component having a benzophenone structure can be a relatively flexible monomer in terms of molecular structure because a pair of benzene rings can be bent based on a carbonyl group, and the flexible monomer can help increase the thermal expansion coefficient of the polyimide resin derived from the polyamic acid composition.

However, the coefficient of thermal expansion of most inorganic materials, including amorphous or crystalline silicon, belongs to the side which is small as 9 ppm/° C. or less, or 8 ppm/° C. or less, whereby it may be quite undesirable in terms of dimensional stability that the polyimide resin capable being bonded to the inorganic material has a larger coefficient of thermal expansion.

The coefficient of thermal expansion can generally be reduced when using a rigid monomer in terms of molecular structure. The rigid structure in terms of molecular structure may mean a molecular structure that the main chain between the diamine groups or the carboxyl groups is composed of one benzene ring, and thus the main chain is difficult to be bent.

The second component is a component thus having one benzene ring, which may be pyromellitic dianhydride (PMDA), and may act advantageously such that the polyimide resin derived from the polyamic acid composition of the present invention has a low coefficient of thermal expansion.

However, when only pyromellitic dianhydride having such a rigid structure is used in combination with the third component, the coefficient of thermal expansion of the polyimide resin may be lowered excessively as less than 6 ppm/° C., or 1 ppm/° C. or less, and the polyimide resin converted from the polyamic acid composition may exhibit brittle properties and may have a relatively low elongation.

Therefore, in the present invention, it should be noted that as the aromatic dianhydride-based monomer, the first component is further included together with the second component and the third component.

It can be seen that the first component having a biphenyl structure is not a rigid molecular structure but a more flexible structure compared to the second component, and simultaneously it has a more rigid molecular structure than the third component, and consequently, the first component can be a material between the second component and the third component.

The polyamic acid composition of the present invention may have an elongation of 20% or more due to the first component, and such an elongation may preferably act in a process of forming, for example, a thin film transistor device structure.

In addition, as the first component, the second component and the third component are combined, the polyimide resin derived from the polyamic acid composition of the present invention may have an appropriate coefficient of thermal expansion of 8 ppm/° C. or less, 7.7 ppm/° C. or less, 7.5 ppm/° C. or less, 6 to 8 ppm/° C. or 6 ppm/° C. to 7 ppm/° C., and have an excellent glass transition temperature of 490° C. or more, specifically a glass transition temperature of 495° C. or more, 500° C. or more, 490° C. to 520° C., 490° C. to 510° C. or 500° C. to 550° C. and may have a tensile strength of 350 MPa or more, specifically a tensile strength of 360 MPa or more, 370 MPa or more, 350 to 400 MPa, or 360 to 390 MPa.

In order to realize the foregoing, it is particularly important that the first component and the second component are combined in a preferred content, and accordingly, the present invention provides a preferred content of the first component and the second component.

In one example of this, the content of the first component may be 50 mol % to 70 mol %, 50 mol % to 65 mol %, 55 mol % to 70 mol %, 55 mol % to 65 mol %, 57 mol % to 62 mol %, or 58 mol % to 60 mol %, relative to the total number of moles of the aromatic dianhydride-based monomer.

The content of the second component may be 20 mol % to 40 mol %, 20 mol % to 35 mol %, 25 mol % to 40 mol %, 25 mol % to 35 mol %, 30 mol % to 40 mol %, 32 mol % to 38 mol %, or 35 mol % to 38 mol %, relative to the total number of moles of the aromatic dianhydride-based monomer.

When the content of the first component satisfies the above range, the polyimide resin may exhibit an appropriate level of elongation, coefficient of thermal expansion, and glass transition temperature.

The aromatic dianhydride-based monomer may also further comprise some of other dianhydride components in addition to the first to third components as described above.

Such a dianhydride component may be non-restrictively exemplified by 2,3,3′,4′-biphenyltetracarboxylic dianhydride (a-BPDA), oxydiphthalic dianhydride (ODPA), diphenylsulfone-3,4,3′,4′-tetracarboxylic dianhydride (DSDA), bis(3,4-dicarboxyphenyl)sulfide dianhydride, 2,2-bis(3,4-dicarboxyphenyl)-1,1,1,3,3,3-hexafluoropropane dianhydride, 2,3,3′,4′-benzophenonetetracarboxylic dianhydride, bis(3,4-dicarboxyphenyl)methane dianhydride, 2,2-bis (3,4-dicarboxyphenyl)propane dianhydride, p-phenylenebis(trimellitic monoester acid anhydride), p-biphenylenebis(trimellitic monoester acid anhydride), m-terphenyl-3,4,3′,4′-tetracarboxylic dianhydride, p-terphenyl-3,4,3′,4′-tetracarboxylic dianhydride, 1,3-bis(3,4-dicarboxyphenoxy)benzene dianhydride, 1,4-bis(3,4-dicarboxyphenoxy)benzene dianhydride, 1,4-bis(3,4-dicarboxyphenoxy)biphenyl dianhydride, 2,2-bis[(3,4-dicarboxyphenoxy)phenyl]propane dianhydride (BPADA), 2,3,6,7-naphthalene tetracarboxylic acid dianhydride, 1,4,5,8-naphthalene tetracarboxylic dianhydride, 4,4′-(2,2-hexafluoroisopropylidene)diphthalic acid dianhydride, or the like.

Meanwhile, the diamine component having one benzene ring may have a molecular structure in which the main chain between the diamine groups is composed of one benzene ring, whereby the main chain is difficult to be bent.

As described above, the coefficient of thermal expansion of most inorganic materials, including amorphous or crystalline silicon, is relatively small, and the polyimide resin applied thereto preferably has a coefficient of thermal expansion similar to that of the inorganic material.

The diamine component having one benzene ring may be preferable in that it can reduce the coefficient of thermal expansion, and in another aspect, it may advantageously act to improve the glass transition temperature of the polyimide resin. In addition, the aspect in which the diamine component can offset the increase in the coefficient of thermal expansion due to the second component used in a relatively low content may also be recognized as a preferred factor.

In the diamine component having one benzene ring, a component comprising one or more selected from the group consisting of 1,4-diaminobenzene (PPD), 1,3-diaminobenzene (MPD), 2,4-diaminotoluene, 2,6-diaminotoluene and 3, 5-diaminobenzoic acid may be selected as the diamine component.

Among them, 1,4-diaminobenzene, which is advantageous in improving the tensile strength and can act advantageously to induce the coefficient of thermal expansion to a desirable level in combination with the pyromellitic dianhydride, may be preferred as the diamine component having one benzene ring.

The aromatic diamine-based monomer may comprise a diamine component having one benzene ring in an amount of more than 50 mol %, 60 mol % or more, or 70 mol % to 100 mol % relative to the total number of moles thereof.

When the content of the diamine component satisfies the above range, the polyimide resin may exhibit an appropriate level of elongation, coefficient of thermal expansion, and glass transition temperature.

In addition to the above-described diamine component, the aromatic diamine-based monomer may also further comprise some of other dianhydride components.

Such a diamine component may be non-restrictively exemplified by diaminodiphenyl ethers of CV-4,4′-diaminodiphenyl ether (or oxydianiline, ODA), 3,4′-diaminodiphenyl ether or the like, 4,4′-diaminodiphenylmethane (methylenedianiline, MDA), 3,3′-dimethyl-4,4′-diaminobiphenyl, 2,2′-dimethyl-4,4′-diaminobiphenyl, 2,2′-bis(trifluoromethyl)-4,4′-diaminobiphenyl, 3,3′-dimethyl-4,4′-diaminodiphenylmethane, 3,3′-dicarboxy-4,4′-diaminodiphenylmethane, 3,3′,5,5′-tetramethyl-4,4′-diaminodiphenylmethane, bis(4-aminophenyl)sulfide, 4,4′-diaminobenzanilide, 3,3′-dimethylbenzidine (or o-tolidine), 2,2′-dimethylbenzidine (or m-tolidine), 3,3′-dimethoxybenzidine, 2,2′-dimethoxybenzidine, 3,3′-diaminodiphenyl ether, 3,4′-diaminodiphenyl ether, 4,4′-diaminodiphenyl ether, 3,3′-diaminodiphenylsulfide, 3,4′-diaminodiphenylsulfide, 4,4′-diaminodiphenylsulfide, 3,3′-diaminodiphenylsulfone, 3,4′-diaminodiphenylsulfone, 4,4′-diaminodiphenylsulfone, 3,3′-diaminobenzophenone, 4,4′-diaminobenzophenone, 3,3′-diamino-4,4′-dichlorobenzophenone, 3,3′-diamino-4,4′-dimethoxybenzophenone, 3,3′-diaminodiphenylmethane, 3,4′-diaminodiphenylmethane, 4,4′-diaminodiphenylmethane, 2,2-bis(3-aminophenyl)propane, 2,2-bis(4-aminophenyl)propane, 2,2-bis(3-aminophenyl)-1,1,1,3,3,3-hexafluoropropane, 2,2-bis(4-aminophenyl)-1,1,1,3,3,3-hexafluoropropane, 3,3′-diaminodiphenylsulfoxide and 3,4′-diaminodiphenylsulfoxide, 4,4′-diaminodiphenylsulfoxide, 1,3-bis(3-aminophenyl)benzene, 1,3-bis(4-aminophenyl)benzene, 1,4-bis(3-aminophenyl)benzene, 1,4-bis(4-aminophenyl)benzene, 1,3-bis(4-aminophenoxy)benzene (or TPE-R), 1,4-bis(3-aminophenoxy)benzene (or TPE-Q) 1,3-bis(3-aminophenoxy)-4-trifluoromethylbenzene, 3,3′-diamino-4-(4-phenyl)phenoxybenzophenone, 3,3′-diamino-4,4′-di(4-phenylphenoxy)benzophenone, 1,3-bis(3-aminophenylsulfide)benzene, 1,3-bis(4-aminophenylsulfide)benzene, 1,4-bis(4-aminophenylsulfide)benzene, 1,3-bis(3-aminophenylsulfone)benzene, 1,3-bis(4-aminophenylsulfone)benzene, 1,4-bis(4-aminophenylsulfone)benzene, 1,3-bis[2-(4-aminophenyl)isopropyl]benzene, 1,4-bis[2-(3-aminophenyl)isopropyl]benzene, 1,4-bis[2-(4-aminophenyl)isopropyl]benzene, 3,3′-bis(3-aminophenoxy)biphenyl, 3,3′-bis(4-aminophenoxy)biphenyl, 4,4′-bis(3-aminophenoxy)biphenyl, 4,4′-bis(4-aminophenoxy)biphenyl, bis[3-(3-aminophenoxy)phenyl]ether, bis[3-(4-aminophenoxy)phenyl] ether, bis[4-(3-aminophenoxy)phenyl] ether, bis[4-(4-aminophenoxy)phenyl] ether, bis[3-(3-aminophenoxy)phenyl]ketone, bis[3-(4-aminophenoxy)phenyl]ketone, bis[4-(3-aminophenoxy)phenyl]ketone, bis[4-(4-aminophenoxy)phenyl]ketone, bis[3-(3-aminophenoxy)phenyl]sulfide, bis[3-(4-aminophenoxy)phenyl]sulfide, bis[4-(3-aminophenoxy)phenyl]sulfide, bis[4-(4-aminophenoxy)phenyl]sulfide, bis[3-(3-aminophenoxy)phenyl]sulfone, bis[3-(4-aminophenoxy)phenyl]sulfone, bis[4-(3-aminophenoxy)phenyl]sulfone, bis[4-(4-aminophenoxy)phenyl]sulfone, bis[3-(3-aminophenoxy)phenyl]methane, bis[3-(4-aminophenoxy)phenyl]methane, bis[4-(3-aminophenoxy)phenyl]methane, bis[4-(4-aminophenoxy)phenyl]methane, 2,2-bis[3-(3-aminophenoxy)phenyl]propane, 2,2-bis[3-(4-aminophenoxy)phenyl]propane, 2,2-bis[4-(3-aminophenoxy)phenyl]propane, 2,2-bis[4-(3-aminophenoxy)phenyl]propane (BAPP), 2,2-bis[3-(3-aminophenoxy)phenyl]-1,1,1,3,3,3-hexafluoropropane, 2,2-bis[3-(4-aminophenoxy)phenyl]-1,1,1,3,3,3-hexafluoropropane, 2,2-bis[4-(3-aminophenoxy)phenyl]-1,1,1,3,3,3-hexafluoropropane and 2,2-bis[4-(4-aminophenoxy)phenyl]-1,1,1,3,3,3-hexafluoropropane.

As described above, the polyamic acid composition according to the present invention has desirable adhesion to implement a display substrate due to the third component, and in addition to this, as the first component and the second component are combined, various properties required for polyimide may be in an appropriate level.

<Additives>

The polyamic acid composition according to the present invention may further comprise at least one of a silane-based coupling agent and a silicone-based surfactant.

A part of the silane-based coupling agent may be bonded to the amic acid groups of the polyamic acid composition or the imide groups of the polyimide resin in which the amic acid groups have been converted, and the other part may be bonded to oxygen or silicon present in an inorganic material, for example, a silicone-based material, for example, an amorphous or crystalline silicon substrate.

By this action, the silane-based coupling agent can increase the adhesion of the polyimide resin derived from curing of the polyamic acid composition within the range of 0.05 to 0.1 N/cm.

However, since excessive use of the silane-based coupling agent may cause deterioration in physical properties of the polyimide resin derived from the polyamic acid composition, it may be preferably used in an extremely limited content.

As an example of this, the silane-based coupling agent may be included in the polyamic acid composition in an amount of 0.01 to 0.05 wt %, 0.01 to 0.03 wt %, or 0.018 to 0.022 wt % relative to the weight of the polyamic acid solid content of the polyamic acid composition.

The silane-based coupling agent that may be preferably included in the polyamic acid composition of the present invention may comprise non-restrictively one or more selected from the group consisting of (3-aminopropyl)trimethoxysilane (APTMS), aminopropyltriethoxysilane, 3-(2-aminoethylamino)propyl-dimethoxymethylsilane, 3-glycidoxypropyldimethoxymethylsilane and 2-(3,4-epoxycyclohexyl)trimethoxysilane, particularly preferably, may comprise one or more selected from the group consisting of 3-aminopropyltrimethoxysilane, aminopropyltriethoxysilane and 3-(2-aminoethylamino)propyl-dimethoxymethylsilane, which contain amine groups, thereby being easily bonded to the amic acid group of the polyamic acid composition or the imide group of the polyimide resin in which the amic acid groups have been converted, and most preferably, may be 3-aminopropyltrimethoxysilane, which may be advantageous in preventing decrease in physical properties of the polyimide resin derived from the polyamic acid composition.

For example, upon applying a polyamic acid composition to an inorganic substrate or the like, the silicone-based surfactant may preferably act to form a film with a uniform thickness by allowing the polyamic acid composition having fluidity to spread well on the substrate.

However, if the surfactant is included in an excessive content, a phenomenon that at least a part of the polyamic acid composition is aggregated may occur, thereby making film formation difficult and causing decrease in the physical properties of the polyimide resin derived from curing of the polyamic acid composition, and on the contrary, the surfactant contained in a small amount is not preferable because it does not help with the advantages related to film formation.

Accordingly, the preferred content of the surfactant may be 0.001 to 0.02 wt %, 0.005 to 0.015 wt %, or 0.008 to 0.012 wt % relative to the weight of the polyamic acid solid content of the polyamic acid composition.

The type of the surfactant is not particularly limited, but a silicone-based surfactant may be preferred. The silicone-based surfactant may be easily obtained commercially, and for example, BYK's ‘BYK-378’ may be used as the silicone-based surfactant. However, the above example is for aiding in the implementation of the present invention, and the surfactant that can be used in the present invention is not limited to the above example.

The polyamic acid composition may also further comprise at least one curing accelerator selected from acetic anhydride (AA), propionic acid anhydride, and lactic acid anhydride, quinoline, isoquinoline, β-picoline (BP) and pyridine.

When the polyamic acid composition is formed into a film and then converted into a polyimide resin, such a curing accelerator may help to obtain a desired polyimide resin by promoting a ring closure reaction through dehydrating action on the polyamic acid.

The curing accelerator may be included in an amount of 0.05 moles to 20 moles per 1 mole of the amic acid group in the polyamic acid.

When the curing accelerator satisfies the above range, a polyimide resin capable of casting in the form of a thin film and having an excellent strength may be prepared by accelerating dehydration and/or ring closure reaction.

The polyamic acid composition may further comprise a filler for the purpose of improving various properties of the polyimide resin such as sliding properties, thermal conductivity and loop hardness of the polyimide resin derived from the polyamic acid composition.

The filler is not particularly limited, but a preferred example may include silica, titanium oxide, alumina, silicon nitride, boron nitride, calcium hydrogen phosphate, calcium phosphate, mica, and the like.

The average particle diameter of the filler is not particularly limited, which may be determined depending on the characteristics of the polyimide resin to be modified and the type of filler to be added. In one example, the average particle diameter of the filler may be 0.05 μm to 100 μm, 0.1 μm to 75 μm, 0.1 μm to 50 μm, or 0.1 μm to 25 μm.

If the average particle diameter satisfies this range, the modification effect is excellent, and the surface property of the polyimide resin and its mechanical properties may be induced.

In addition, the additive amount of the filler is not particularly limited, which may be determined by the properties of the polyimide resin to be modified or the particle diameter of the filler, and the like.

In one example, the additive amount of the filler is 0.01 parts by weight to 100 parts by weight, 0.01 parts by weight to 90 parts by weight, or 0.02 parts by weight to 80 parts by weight, relative to 100 parts by weight of the polyamic acid composition.

If the additive amount of the filler satisfies this range, the modification effect by the filler is excellent, and the mechanical properties of the polyimide resin may be improved. The method of adding the filler is not particularly limited, and it goes without saying that any known method may be used.

<Method for Preparing Polyamic Acid Composition>

A method of producing a polyamic acid constituting the polyamic acid composition may include, for example,

(1) a method of putting the entire amount of a diamine-based monomer in an organic solvent, and then adding a dianhydride-based monomer so as to be substantially equimolar to the moles of the diamine-based monomer, thereby polymerizing them;

(2) a method of putting the entire amount of a dianhydride-based monomer in an organic solvent, and then adding a diamine-based monomer so as to be substantially equimolar to the moles of the dianhydride-based monomer, thereby polymerizing them;

(3) a method of putting some components of a diamine-based monomer in an organic solvent, and then mixing some components of a dianhydride-based monomer in a ratio of about 95 mol % to 105 mol % with respect to the reaction component, and then adding the remaining diamine-based monomer components and continuously adding the remaining dianhydride-based monomer components, so that the diamine-based monomer and the dianhydride-based monomer have a substantially equimolar amount, thereby polymerizing them;

(4) a method of putting a dianhydride-based monomer in an organic solvent, and then mixing some components of a diamine compound in a ratio of 95 mol % to 105 mol with respect to the reaction component, and then adding other dianhydride-based monomer components and continuously adding the remaining diamine-based monomer components, so that the diamine-based monomer and the dianhydride-based monomer have a substantially equimolar amount, thereby polymerizing them; and

(5) a method of reacting some diamine-based monomer components and some dianhydride-based monomer components in an organic solvent so that any one is in excess to form a first polymer, and reacting some diamine-based monomer components and some dianhydrides in another organic solvent so that any one is in excess to form a second polymer, and then mixing the first and second polymers to complete polymerization, wherein when the diamine-based monomer component is excessive upon forming the first polymer, the dianhydride-based monomer component is in excess in the second polymer, and when the dianhydride-based monomer component is excessive in the first polymer, the diamine-based monomer component is in excess in the second polymer, and the first and second polymers are mixed, so that the entire diamine-based monomer component and dianhydride-based monomer component used in these reactions have a substantially equimolar amount, thereby polymerizing them, and the like.

However, the above methods are examples to aid in the implementation of the present invention, and the scope of the present invention is not limited thereto, and it goes without saying that any known method may be used.

The organic solvent is not particularly limited as long as it is a solvent in which the polyamic acid can be dissolved, but as one example, it may be an aprotic polar solvent.

A non-limiting example of the aprotic polar solvent may include an amide-based solvent such as N,N-dimethylformamide (DMF) and N,N-dimethylacetamide (DMAc), and a phenolic solvent such as p-chlorophenol and o-chlorophenol, N-methyl-pyrrolidone (NMP), gamma-butyrolactone (GBL) and Diglyme, and the like, and these may be used alone or in combination of two or more.

In some cases, an auxiliary solvent such as toluene, tetrahydrofuran, acetone, methyl ethyl ketone, methanol, ethanol and water may also be used to adjust the solubility of the polyamic acid.

In one example, the organic solvent that can be particularly preferably used in the preparation of the polyamic acid composition of the present invention may be N-methyl-pyrrolidone, N,N′-dimethylformamide and N,N′-dimethylacetamide.

The polyamic acid composition thus prepared may have a viscosity of 3,000 cP to 7,000 cP, 3,500 cP to 6,500 cP, or 4,000 cP to 5,500 cP as measured at 23° C. The viscosity may be a viscosity measured with a Brookfield viscometer on an RV-7 spindle under conditions of a temperature of 23° C. and a rotation speed of 0.5 rpm. In the present application, the polyamic acid composition may have a solid content of 5 to 30%, 10 to 25%, or 12 to 20%. When the viscosity of the polyamic acid composition satisfies the above range, the fluidity of the polyamic acid composition may be improved to facilitate the application process and the adhesion of the polyimide resin may be improved.

Method for Manufacturing Display Substrate Using Polyamic Acid Composition

The present invention provides a method for manufacturing a display substrate using the polyamic acid compositions of the previous embodiments.

Specifically, the method may comprise

a step of applying the polyamic acid composition on an amorphous or crystalline silicon substrate.

In addition, the manufacturing method of the present application comprises steps of performing first heat treatment of the polyamic acid composition at 20° C. to 40° C.;

performing second heat treatment of the polyamic acid composition at 40° C. to 200° C.; and

performing third heat treatment of the polyamic acid composition at 200° C. to 500° C.

Through the first heat treatment, second heat treatment and third heat treatment steps, the polyamic acid composition generates a polyimide resin comprising imide groups that the amic acid groups of the polyamic acid are subjected to ring-closure and dehydration reaction, which is cured by volatilizing the organic solvent, and when the third heat treatment is completed, the polyimide resin may be cured and bonded on the amorphous or crystalline silicon substrate.

In one specific example, in the step of applying the polyamic acid composition on the amorphous or crystalline silicon substrate, the polyamic acid composition may be applied so that the polyimide resin produced after the polyamic acid composition is cured has a thickness of 0.5 μm to 20 μm, 2 μm to 18 μm, or 2 to 5 μm.

In one specific example, the first heat treatment, second heat treatment and third heat treatment steps may be each independently performed at two or more variable heating rates selected from the range of 3° C./min to 7° C./min, or one constant heating rate selected from the above range.

The manufacturing method according to the present invention may further comprise steps of:

forming a thin film transistor (TFT) on the polyimide resin, and

irradiating the amorphous or crystalline silicon substrate with a laser for a predetermined time to remove the amorphous or crystalline silicon substrate from the polyimide resin, wherein

it may be 0.01 N/cm or less between the polyimide resin and the amorphous or crystalline silicon substrate as measured after the laser irradiation.

The adhesion after the laser irradiation is at a very insignificant level, which may be a level where the bonding state with the amorphous or crystalline silicon substrate cannot be substantially maintained, and accordingly, for example, after the process of forming a thin film transistor device structure, the polyimide resin derived from the polyamic acid composition can be easily peeled off from the amorphous or crystalline silicon substrate, and its shape can also be maintained intact.

In the step of removing the amorphous or crystalline silicon substrate, the laser may be performed by an LLO (laser lift off) method.

The energy density (E/D) of the laser may be 180 mJ/cm² or less, and preferably 150 mi/cm² or less.

### Advantageous Effects

As described above, the polyamic acid composition according to the present invention may exhibit the most desirable adhesion to an amorphous or crystalline silicon substrate by the third component having a benzophenone structure.

The polyamic acid composition according to the present invention can also implement a polyimide resin in which various physical properties required for manufacturing a display substrate are indwelled at an appropriate level by a combination of a dianhydride-based monomer and a diamine-based monomer, which comprise specific components.

### BEST MODE

Hereinafter, the action and effect of the invention will be described in more detail through specific examples of the invention. However, these examples are only presented as examples of the invention, and the scope of the invention is not determined thereby.

### Example 1

To a reactor filled with NMP at 40° C. BPDA (first component), PMDA (second component), BTDA (third component) as aromatic dianhydride-based monomers, and PPD as an aromatic diamine-based monomer were added in the molar ratios shown in Table 1 below, and stirred for about 30 minutes to polymerize a polyamic acid.

The following substances were added thereto, and the aging process was performed for about 2 hours to prepare a final polyamic acid composition. At this time, the viscosity of the polyamic acid composition was about 5,100 cP.
Silane-based coupling agent: 0.02 wt % of 3-aminopropyltrimethoxysilane (based on the weight of the polyamic acid solid content)
Silicone-based surfactant: 0.01 wt % of BYK's ‘BYK-378’ (based on the weight of the polyamic acid solid content)
Additive: 10 wt % of isoquinoline (based on the weight of the polyamic acid solid content)

### Example 2

A polyamic acid composition having a viscosity of about 5,000 cP was prepared in the same manner as in Example 1, except that the molar ratio of BPDA (first component), PMDA (second component) and BTDA (third component) was changed to the molar ratio shown in Table 1 below and the components were added thereto.

### Example 3

A polyamic acid composition having a viscosity of about 5,100 cP was prepared in the same manner as in Example 1, except that the molar ratio of BPDA (first component), PMDA (second component) and BTDA (third component) was changed to the molar ratio shown in Table 1 below and the components were added thereto.

### Example 4

A polyamic acid composition having a viscosity of about 4,800 cP was prepared in the same manner as in Example 1, except that the molar ratio of BPDA (first component). PMDA (second component) and BTDA (third component) was changed to the molar ratio shown in Table 1 below and the components were added thereto.

### Comparative Example 1

A polyamic acid composition having a viscosity of about 4,800 cP was prepared in the same manner as in Example 1, except that and BTDA (third component) was excluded as the component of the aromatic dianhydride-based monomer, the molar ratio of BPDA (first component) and PMDA (second component) was changed to the molar ratio shown in Table 1 below and the components were added thereto.

### Comparative Example 2

A polyamic acid composition having a viscosity of about 5,300 cP was prepared in the same manner as in Example 1, except that and BTDA (third component) was excluded as the component of the aromatic dianhydride-based monomer, the molar ratio of BPDA (first component) and PMDA (second component) was changed to the molar ratio shown in Table 1 below and the components were added thereto.

### Comparative Example 3

A polyamic acid composition having a viscosity of about 4,750 cP was prepared in the same manner as in Example 1, except that and BTDA (third component) was excluded as the component of the aromatic dianhydride-based monomer, the molar ratio of BPDA (first component) and PMDA (second component) was changed to the molar ratio shown in Table 1 below and the components were added thereto.

### Comparative Example 4

A polyamic acid composition having a viscosity of about 4,950 cP was prepared in the same manner as in Example 1, except that and BTDA (third component) was excluded as the component of the aromatic dianhydride-based monomer, the molar ratio of BPDA (first component) and PMDA (second component) was changed to the molar ratio shown in Table 1 below and the components were added thereto.

### Comparative Example 5

A polyamic acid composition having a viscosity of about 5,100 cP was prepared in the same manner as in Example 1, except that the molar ratio of BPDA (first component). PMDA (second component) and BTDA (third component) was changed to the molar ratio shown in Table 1 below and the components were added thereto.

### Comparative Example 6

A polyamic acid composition having a viscosity of about 5,100 cP was prepared in the same manner as in Example 1, except that the molar ratio of BPDA (first component), PMDA (second component) and BTDA (third component) was changed to the molar ratio shown in Table 1 below and the components were added thereto.

TABLE 1

| | | Composition | | | | Molar ratio | | | |
|---|---|---|---|---|---|---|---|---|---|
| | | Dianhydride-based monomer | | | Diamine- | Dianhydride-based monomer | | | Diamine- |
| | | First | Second | Third | based | First | Second | Third | based |
| | | component | component | component | monomer | component | component | component | monomer |
| Example | 1 | BPDA | PMDA | BTDA | PPD | 60 | 38 | 7 | 100 |
| | 2 | BPDA | PMDA | BTDA | PPD | 60 | 35 | 5 | 100 |
| | 3 | BPDA | PMDA | BTDA | PPD | 55 | 40 | 5 | 100 |
| | 4 | BPDA | PMDA | BTDA | PPD | 65 | 32 | 3 | 100 |
| Comparative | 1 | BPDA | PMDA | — | PPD | 60 | 40 | — | 100 |
| Example | 2 | BPDA | PMDA | — | PPD | 70 | 30 | — | 100 |
| | 3 | BPDA | PMDA | — | PPD | 80 | 70 | — | 100 |
| | 4 | BPDA | PMDA | — | PPD | 50 | 50 | — | 100 |
| | 5 | BPDA | PMDA | BTDA | PPD | 60 | 39 | 1 | 100 |
| | 6 | BPDA | PMDA | BTDA | PPD | 60 | 33 | 7 | 100 |

### Experimental Example 1: Adhesion Test of Polyimide Resin

The polyamic acid compositions prepared in Examples 1 to 4 and Comparative Examples 1 to 6 were each cast at 30 μm on an amorphous silicon substrate with a width of 1 cm*a length of 10 cm and dried in a temperature range of 20° C. to 460° C. to manufacture a laminate to which the polyimide resin in the form of a thin film having an average thickness of about 15 to 17 μm were bonded.

With respect to the laminate thus manufactured, the first adhesion (before laser treatment), curl test, and second adhesion (after laser treatment) of the polyimide resin were evaluated using the following methods.
First adhesion: The required force is measured, while attaching a tape with a width of 1 cm to the end of the polyimide resin and peeling the polyimide resin from the substrate using this tape.
Curl test: The manufactured laminate was heat-treated at a temperature of about 400° C. for about 1 hour, and then it was confirmed whether curls occurred at the edge sites of the polyimide resin on the amorphous silicon substrate.
Second adhesion: After irradiating the amorphous silicon substrate with a laser having a wavelength of 308 nm at 150 mJ/cm², the required force is measured, while attaching a tape with a width of 1 cm to the end of the polyimide resin and peeling the polyimide resin from the substrate using this tape.
The adhesion was measured while peeling it at a peel rate of 20 mm/min and a peel angle of 180°, according to ASTM D 3359.

TABLE 2

| | | First adhesion | Curl occurrence | Second adhesion |
|---|---|---|---|---|
| | | (N/cm) | (◯, X) | (N/cm) |
| Example | 1 | 0.07 | X | 0.01 or less |
| | 2 | 0.08 | X | 0.01 or less |
| | 3 | 0.07 | X | 0.01 or less |
| | 4 | 0.07 | X | 0.01 or less |
| Comparative | 1 | 0.03 | ◯ | 0.01 or less |
| Example | 2 | 0.03 | ◯ | 0.01 or less |
| | 3 | 0.03 | ◯ | 0.01 or less |
| | 4 | 0.03 | ◯ | 0.01 or less |
| | 5 | 0.03 | ◯ | 0.01 or less |
| | 6 | 0.12 | X | 0.05 |

### Experimental Example 2: Physical Property Test of Polyimide Resin

The polyamic acid compositions prepared in Examples 1 to 5 and Comparative Examples 1 to 6 were applied in the form of a thin film to a stainless-based support and then heat-treated in the temperature range of 20° C. to 350° C., and subsequently peeled from the support to produce polyimide resins in the form of films having average thicknesses of about 15 to 17 μm, respectively.

The polyimide resin thus produced was tested for physical properties in the following methods, and the results were shown in Table 3 below.

(1) Coefficient of Thermal Expansion (CTE)

The coefficient of thermal expansion was measured in the range of 100 to 350° C. using TMA.

(2) Glass Transition Temperature (T_{g})

As for the glass transition temperature, the loss elastic modulus and the storage elastic modulus of each polyimide resin were calculated using TMA, and in their tangent graphs, the inflection point was measured as the glass transition temperature.

(3) Thermal Decomposition Temperature (T_{d})

While increasing the temperature at a temperature increase rate of 10° C./min in nitrogen, the temperature was measured when the initial weight of the polyimide resin decreased by 1%, using a thermogravimetric analyzer (TG-DTA2000).

(4) Tensile Strength

The tensile strength was measured by the method presented in KS6518.

(5) Elongation

The elongation was measured by the method presented in ASTM D1708.

(6) Transmittance

Using the HunterLab's ColorQuesetXE model, the transmittance of a wavelength of 550 nm was measured in the visible light region by the method presented in ASTM D1003.

Table 3

| | | CTE | T_{g} | T_{d} | Tensile strength | Elongation | Transmittance |
|---|---|---|---|---|---|---|---|
| | | (ppm/° C.) | (° C.) | (° C.) | (MPa) | (%) | (%) |
| Example | 1 | 6.2 | 507 | 567 | 385 | 23.8 | 60.8 |
| | 2 | 6.4 | 509 | 563 | 388 | 23.4 | 61.0 |
| | 3 | 6.7 | 506 | 561 | 382 | 22.7 | 60.7 |
| | 4 | 7.7 | 495 | 559 | 374 | 24.8 | 61.3 |
| Comparative | 1 | 6.3 | 508 | 566 | 382 | 23.8 | 60.7 |
| Example | 2 | 11.8 | 481 | 569 | 347 | 27.9 | 62.1 |
| | 3 | 14.1 | 435 | 565 | 374 | 34.8 | 65.7 |
| | 4 | 5.8 | 521 | 556 | 398 | 15.2 | 57.1 |
| | 5 | 6.1 | 508 | 563 | 378 | 27.8 | 60.4 |
| | 6 | 9.5 | 489 | 561 | 382 | 17.5 | 61.8 |

From the results of Experimental Example 1, Examples exhibited an appropriate level of adhesion to the amorphous silicon substrate, that is, first adhesion belonging to 0.05 to 0.1 N/cm. The advantage of the first adhesion belonging to the above range can be confirmed indirectly through the occurrence of curls. According to Table 2, in Examples, even when heat treatment was performed at a high temperature of 400° C. for a predetermined time, no curl occurred at all.

If the adhesion is low, the bonding state between the polyimide resin and the amorphous silicon substrate is released at a high temperature of 400° C., and curls may occur in which the ends of the polyimide resin are rolled inward. Really, most of Comparative Examples exhibited lower first adhesion than that of Examples, and curls occurred in all.

These results suggest that the adhesion of at least 0.05 N/cm is required for a TFT process performed at high temperatures, and it can be seen that Examples according to the present invention exhibits the desirable adhesion for the TFT process. In another aspect, Examples showed extremely insignificant adhesion (second adhesion) after treatment with a laser for removal of the amorphous silicon substrate, and it can be expected therefrom that when the first adhesion is satisfied, the amorphous silicon substrate can be peeled off well from the polyimide resin.

Meanwhile, in Comparative Examples 1 to 5, it can be confirmed that the first adhesion has been out of the range of 0.05 to 0.1 N/cm. In the relevant Comparative Example, curls occurred at a high temperature due to such low first adhesion, and it can be expected that they are unsuitable for manufacturing a display substrate requiring a high temperature process.

Comparative Example 6 is a case where the first adhesion is excessive, wherein in particular, it can be confirmed that the second adhesion after laser treatment is also at a very high level, and unlike Examples, it suggests therefrom that it will be difficult for the amorphous silicon substrate to peel off well from the polyimide resin after laser irradiation.

The results of Experimental Example 2 show that the polyimide resin embodied according to the present invention satisfies all of various properties required for manufacturing a display substrate, and when linked with the results of Experimental Example 1, Examples all exhibit a desirable level of adhesion together with the above properties.

On the contrary, in Comparative Examples, at least one characteristic is not satisfied with poor adhesion, whereby it can be seen that they are unreasonable to be used as a display substrate.

Therefore, it can be seen from the results of Table 3 that the monomer combination and the combination ratio of the present invention are effective for the implementation of the polyamic acid composition.

Although the foregoing has been described with reference to the examples of the present invention, those having ordinary knowledge in the field to which the present invention belongs will be able to perform various applications and modifications within the scope of the present invention based on the above contents.

1. A polyamic acid composition
comprising a polyamic acid polymer in which an aromatic dianhydride-based monomer and an aromatic diamine-based monomer are polymerized,
wherein the aromatic dianhydride-based monomer comprises a first component having a biphenyl structure, a second component having one benzene ring and a third component having a benzophenone structure, and
the polyamic acid composition has, in a cured state on a substrate of amorphous or crystalline silicon, adhesion of 0.05 to 0.1 N/cm with the amorphous or crystalline silicon, and
has, in a cured state on a substrate of amorphous or crystalline silicon, adhesion of 0.01 N/cm or less as measured after irradiation with a laser having a wavelength of 308 nm at 150 mJ/cm².

2. The polyamic acid composition according to claim 1,
wherein the content of the first component is 50 mol % to 70 mol %, and the content of the second component is 20 mol % to 40 mol %, relative to the total number of moles of the aromatic dianhydride-based monomer.

3. The polyamic acid composition according to claim 1,
wherein the content of the component having the benzophenone structure is more than 1 mol % to less than 7 mol % relative to the total number of moles of the aromatic dianhydride-based monomer.

4. The polyamic acid composition according to claim 1,
wherein the first component is one or more selected from the group consisting of 3,3′,4,4′-biphenyltetracarboxylic dianhydride (BPDA) and 2,3,3′,4′-biphenyltetracarboxylic dianhydride (a-BPDA).

5. The polyamic acid composition according to claim 1,
wherein the second component is pyromellitic dianhydride (PMDA).

6. The polyamic acid composition according to claim 1,
wherein the third component is 3,3′,4,4′-benzophenone tetracarboxylic dianhydride (BTDA).

7. The polyamic acid composition according to claim 1,
wherein the aromatic diamine-based monomer is a diamine component having one benzene ring in an amount of more than 50 mol % relative to the total number of moles thereof.

8. The polyamic acid composition according to claim 7,
wherein the diamine component having one benzene ring is one or more selected from the group consisting of 1,4-diaminobenzene (PPD), 1,3-diaminobenzene (MPD), 2,4-diaminotoluene, 2,6-diaminotoluene and 3,5-diaminobenzoic acid.

9. The polyamic acid composition according to claim 7,
wherein the diamine component having one benzene ring is 1,4-diaminobenzene.

10. The polyamic acid composition according to claim 1,
further comprising at least one of a silane-based coupling agent and a silicone-based surfactant.

11. The polyamic acid composition according to claim 11,
wherein the silane-based coupling agent
is contained in an amount of 0.01 to 0.05 wt % relative to the weight of the polyamic acid solid content of the polyamic acid composition; and
comprises one or more selected from the group consisting of (3-aminopropyl)trimethoxysilane (APTMS), aminopropyltriethoxysilane, 3-(2-aminoethylamino)propyl-dimethoxymethylsilane, 3-glycidoxypropyldimethoxymethylsilane and 2-(3,4-epoxycyclohexyl)trimethoxysilane.

12. The polyamic acid composition according to claim 11,
wherein the silicone-based surfactant is contained in an amount of 0.001 to 0.02 wt % relative to the weight of the polyamic acid solid content of the polyamic acid composition.

13. The polyamic acid composition according to claim 1,
wherein the polyamic acid of the polyamic acid composition has a viscosity of 3,000 to 7,000 cP as measured at 23° C.

14. The polyamic acid composition according to claim 1,
wherein a polyimide resin prepared from the polyamic acid composition
has a glass transition temperature of 490° C. or higher,
has a thermal decomposition temperature of 555° C. or higher, and
has a coefficient of thermal expansion of 8 ppm/° C. or less.

15. The polyamic acid composition according to claim 14,
wherein the polyimide resin has a tensile strength of 350 MPa or more, elongation of 20% or more and transmittance of 60% or more.

16. A method for manufacturing a display substrate comprising a step of applying the polyamic acid composition according to claim 1 on an amorphous or crystalline silicon substrate.

17. The method for manufacturing a display substrate according to claim 16, wherein the method comprises steps of performing first heat treatment of the polyamic acid composition at 20° C. to 40° C.;
performing second heat treatment of the polyamic acid composition at 40° C. to 200° C.; and
performing third heat treatment of the polyamic acid composition at 200° C. to 500° C., and
wherein through the first heat treatment, second heat treatment and third heat treatment steps, the polyamic acid composition generates a polyimide resin comprising imide groups that the amic acid groups of the polyamic acid are subjected to ring-closure and dehydration reaction, which is cured by volatilizing the organic solvent, and when the third heat treatment is completed, the polyimide resin is cured and bonded on the amorphous or crystalline silicon substrate.

18. The method for manufacturing a display substrate according to claim 17,
wherein the first heat treatment, second heat treatment and third heat treatment steps are each independently performed at two or more variable heating rates selected from the range of 3° C./min to 7° C./min, or one constant heating rate selected from the above range.

19. The method for manufacturing a display substrate according to claim 17, wherein the method comprises steps of:
forming a thin film transistor (TFT) on the polyimide resin, and
irradiating the amorphous or crystalline silicon substrate with a laser for a predetermined time to remove the amorphous or crystalline silicon substrate from the polyimide resin, and
wherein the adhesion between the polyimide resin and the amorphous or crystalline silicon substrate as measured after the laser irradiation is 0.01 N/cm or less.
